(19) United States
(12) Patent Application Publication
(10) Pub. No.: US 2026/0123526 A1
(43) Pub. Date: Apr. 30, 2026

(54) ELECTRONIC DEVICE WITH DOUBLE SIDED HYBRID INTERCONNECTION

(71) Applicant: Texas Instruments Incorporated, Dallas, TX (US)

(72) Inventors: Yi Yan, San Jose, CA (US); Sreeram Nasum S, Bangalore (IN); Suvadip Banerjee, Bangalore (IN)

(21) Appl. No.: 18/925,819

(22) Filed: Oct. 24, 2024

(51) Int. Cl. H01L 25/065; H01L 23/00; H01L 23/31; H01L 23/498; H01L 23/538; H01L 25/00

(52) U.S. Cl. CPC H10W 90/00; H10W 70/60; H10W 70/611; H10W 74/111; H10W 90/701; H10W 90/22; H10W 90/724; H10W 90/755

(57) ABSTRACT

An electronic device includes a substrate having opposite first and second sides, the first side attached to a metal structure, as well as a first semiconductor die attached to the first side of the substrate, a bond wire connected to the first semiconductor die, and a second semiconductor die attached to the second side of the substrate. A method of fabricating an electronic device includes attaching a first semiconductor die to first side of a substrate, attaching an opposite second side of the substrate to a lead frame, connecting a bond wire to a conductive feature of the first semiconductor die, and forming flip chip connections to attach a second semiconductor die to conductive features of an opposite second side of the substrate.

### BACKGROUND

Electronic devices, such as integrated circuits, are often used in isolated power applications where smaller package sizes and increased power density are important. Compact designs can use multiple device dies and possibly integrated magnetics and communications circuitry in a shared package and may sometimes be referred to as multichip modules (MCMs). However, incorporation of further circuits for power isolation, integrated communications and other features of shared package devices is limited without increasing the package size.

### SUMMARY

In one aspect, an electronic device includes a substrate having opposite first and second sides, the first side attached to a metal structure, a first semiconductor die attached to the first side of the substrate, a bond wire connected to the first semiconductor die, and a second semiconductor die attached to the second side of the substrate.

In another aspect, a system includes a circuit board having a conductive feature, and an electronic device that includes a conductive terminal that is soldered to the conductive feature of the circuit board, a substrate having opposite first and second sides, the first side attached to a metal structure, a first semiconductor die attached to the first side of the substrate, a bond wire connected to the first semiconductor die, and a second semiconductor die attached to the second side of the substrate.

In a further aspect, a method includes attaching a first semiconductor die to first side of a substrate, attaching the first side of the substrate to a lead frame, connecting a bond wire to a conductive feature of the first semiconductor die, and forming flip chip connections to attach a second semiconductor die to conductive features of an opposite second side of the substrate.

### BRIEF DESCRIPTION OF THE DRAWINGS

FIG. 1 is a partial sectional side elevation view of a semiconductor device with having semiconductor dies attached to bottom and top sides of a substrate taken along line 1-1 of FIG. 1A.

FIG. 1A is a top perspective view of the semiconductor device of FIG. 1.

FIG. 1B is another partial sectional side elevation view of the semiconductor device taken along line 1B-1B of FIG. 1A.

FIG. 2 is a flow diagram of a method of fabricating a semiconductor device.

FIGS. 3-11 are partial sectional side elevation views of the semiconductor device of FIGS. 1-1B undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. Described examples include doped regions of various semiconductor structures which may be characterized as p-doped and/or n-doped regions or portions and include regions that have majority carrier dopants of a particular type, such as n-type dopants or p-type dopants, and such regions or portions should be interpreted as having the conductivity type as n-type or p-type, respectively. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various disclosed structures and methods of the present disclosure may be beneficially applied to manufacturing a semiconductor device such as an integrated circuit. While such examples may be expected to provide various improvements, no particular result is a requirement of the present disclosure unless explicitly recited in a particular claim.

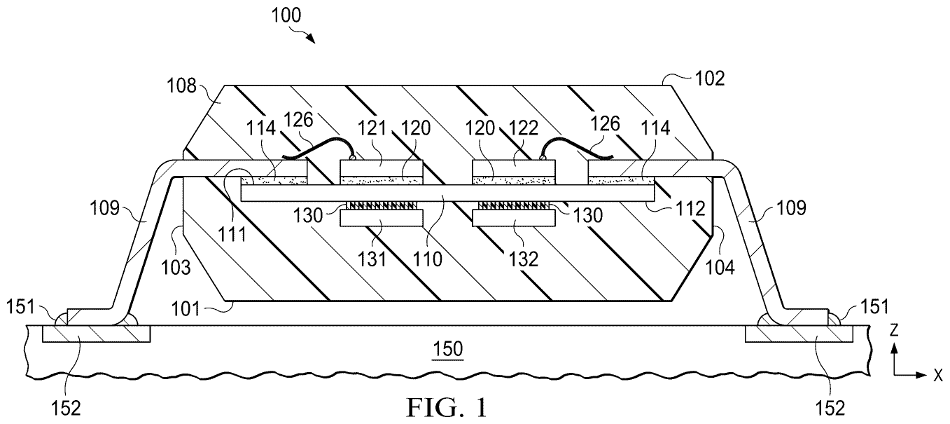

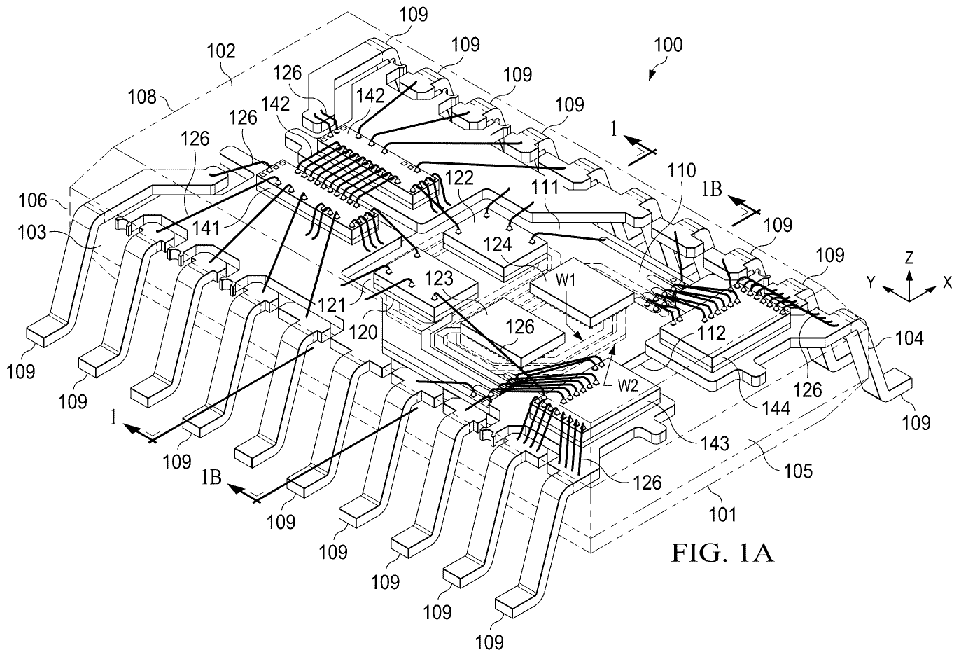

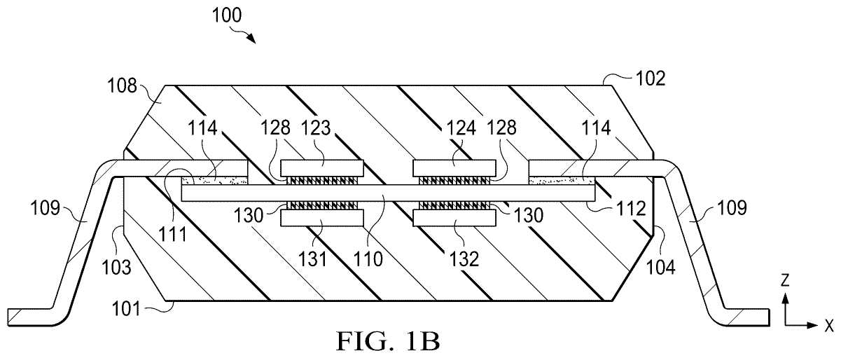

FIGS. 1-1B show an example electronic device 100, which may also be referred to as a semiconductor device or an integrated circuit (IC) with a double sided hybrid interconnection of semiconductor dies on two opposite sides of a substrate to facilitate enhanced integration and high power density without increasing a shared package size. The improved integration can be used in augmenting power isolation with integrated magnetic circuits and components, improved on-board communications. FIG. 1 shows a partial sectional side view of the semiconductor device 100 taken along line 1-1 of FIG. 1A, FIG. 1A shows a top perspective view, and FIG. 1B shows a partial sectional side view taken along line 1B-1B of FIG. 1A.

The electronic device 100 is illustrated in an example three-dimensional space with a first direction X, an orthogonal (e.g., perpendicular) second direction Y, and a third direction Z that is orthogonal (e.g., perpendicular) to the respective first and second directions X and Y. The electronic device 100 has a bottom or first side 101 and an opposite top or second side 102 that are spaced apart from one another along the third direction Z, as well as opposite lateral third and fourth sides 103 and 104, respectively, spaced apart from one another along the first direction X, as well as opposite fifth and sixth ends or sides 105 and 106 (FIG. 1A) that are spaced apart from one another along the second direction Y.

The sides 101-106 in one example are defined by a molded package structure 108 that encloses circuitry and components of the electronic device 100. In another example, the package structure 108 can be a ceramic structure. The electronic device 100 also includes leads 109 made of a conductive metal, such as aluminum or copper or alloys thereof. The illustrated leads 109 are gullwing leads that extend outward from a respective one of the third and fourth sides 103, 104 and downward to form a landing portion below the bottom or first side 101 of the electronic device 100. In other examples, different forms and types of leads or conductive terminals can be used, such as “J” leads or leads of a no-lead (e.g., QFN) package (not shown). Other implementations can include leads on one or more sides 103-106 and/or along the bottom or first side 101.

The electronic device 100 includes a substrate 110. The substrate 110 has a top or first side 111 and an opposite bottom or second side 112. The first side 111 is attached to a metal structure inside the package structure 108, such as interior portions of one or more of the conductive metal leads 109 or die attach pads or other support structures of the electronic device 100. As best shown in FIG. 1A, the substrate 110 is approximately rectangular and four corners of the first side 111 of the substrate 110 are attached to bottom sides of portions of four corresponding metal structures by an adhesive 114 (FIGS. 1 and 1B).

The substrate 110 in one example is a multilevel package substrate that may also be referred to as a routable lead frame (RLF). The substrate 110 has multiple levels or layers of dielectric with conductive metal traces or routing features and conductive metal vias connecting traces of different levels to form electrical interconnections for signal and/or power routing in the electronic device 100. In another example, a single level substrate can be used. The first and second sides 111 and 112 of the substrate 110 have conductive terminals or features to which electrical connections can be made with conductive pillars or bumps of a semiconductor die by flip chip soldering, and/or with bond wires by wirebonding techniques and equipment.

As shown in FIGS. 1 and 1A, the electronic device 100 includes a first semiconductor die 121 that is attached to the first side 111 of the substrate 110 using a conductive or nonconductive die attach film 120. As further shown in FIG. 1, the illustrated example also includes a second semiconductor die 131 that is attached to the second side 112 of the substrate 110 (FIGS. 1 and 1B). The illustrated example has additional dies attached to the substrate 110, although not a requirement of all possible implementations. In the illustrated example, further semiconductor dies are attached to the first side 111 of the substrate 110. These include a semiconductor die 122 attached by a die attach film 120 (FIGS. 1 and 1A), as well as semiconductor dies 123 and 124 (FIGS. 1A and 1B) that have conductive metal terminals 128 (e.g., solder bumps or copper pillars or posts as shown in FIG. 1B) that are flip chip attached (e.g., soldered) to corresponding conductive features on the first side 111 of the substrate 110.

The semiconductor dies 121 and 122 have top side conductive metal features, such as bond pads (not numerically designated), which are coupled by bond wires 126 (FIGS. 1 and 1A) to respective leads 109 of the electronic device 100. The electronic device 100 has other bond wires 126 as shown in FIG. 1A that provide electrical interconnections of various components and structures (e.g., semiconductor dies, leads 109, conductive features or terminals of the substrate 110, etc.). In other examples, discrete electronic components (e.g., surface mount resistors, capacitors, etc.) can be electrically interconnected in circuitry of the electronic device 100, for example, and can be mounted to die attach pads, the substrate 110, or other support structures and can be interconnected by bond wires and/or solder connections (not shown).

As shown in FIGS. 1 and 1B, the example electronic device 100 also includes another semiconductor die 132 attached to the second side 112 of the substrate 110. The second semiconductor die 131 and the semiconductor die 132 have conductive metal terminals 130 (e.g., copper pillars or posts, solder bumps) that are flip chip attached (e.g., soldered) to corresponding conductive features on the second side 112 of the substrate 110 (FIGS. 1 and 1B). In the illustrated example, the corners of the first side 111 of the substrate 110 are attached by the adhesive 114 to bottom sides of support features that are connected to portions of the illustrated leads 109, with the first side 111 facing upwards towards the second side 102 of the package structure 108 and the opposite second side 112 of the substrate 110 facing downward towards the bottom or first side 101 of the package structure 108. The substrate 110 can be inverted in another implementation (not shown), with the first side 111 of the substrate 110 facing the bottom or first side 101 of the package structure 108. In these or other implementations, the substrate 110 can alternatively be mounted to the top sides of the support features.

The electronic device 100 includes further semiconductor dies 141, 142, 143, and 144 (FIG. 1A) that are individually mounted to corresponding support structures (e.g., die attach pads) that are interconnected with corresponding leads 109, for example, using adhesive (not shown). As further shown in FIG. 1A, the semiconductor dies 141-144 include conductive metal features (e.g., bond pads) that are interconnected with other circuits and components of the electronic device 100 by corresponding bond wires 126. The example electronic device has gullwing leads 109 along the opposite third and fourth sides 103 and 104 of the package structure 108. The example leads 109 have interior portions that are enclosed by the package structure 108 as well as external portions that extend outward from a corresponding side 103, 104 (e.g., along the first direction X), and extend downward to bottom or end portions that are configured to be soldered to a host circuit board 150 by solder connections 151 as shown in FIG. 1. Alternatively, the electronic device 100 can be installed in a socket (not shown) with the leads 109 engaged with corresponding conductive features of the socket to form electrical connections to a host system. FIG. 1 shows an example system implementation, in which the system circuit board 150 has traces or pads or other conductive features 152, and the conductive terminals or leads 109 of the electronic device 100 are soldered to respective conductive features 151 of the circuit board 150.

The electronic device 100 in one example is an integrated circuit and can include one or more circuits formed by various components of the semiconductor dies 121-124, 131, 132, 141-144 and any other included passive components (not shown). The illustrated example, moreover, supports electrical isolation between two or more circuits or components thereof, such as high voltage and low voltage domains connected by an isolation transformer. In this example, the substrate 110 includes a first winding W1 (e.g., a transformer primary winding) and a second winding W2 (e.g., a transformer secondary winding). The windings W1 and W2 in this example are formed as conductive metal traces or structures of different levels or layers of the multilevel package substrate 110. The windings W1 and W2 are electrically connected to other circuitry of the electronic device 100 and are magnetically coupled with one another to form a transformer to provide isolation between different circuits.

In the illustrated example, the package structure 108 encloses the substrate 110 with any included integrated windings W1, W2, along with the semiconductor dies 121-124, 131, 132, 141-144, any other included passive components (not shown) and the bond wires 126. The electronic device 100 advantageously provides a small size package that occupies minimal host circuit board space while providing high level of circuit integration with optional magnetic components (e.g., inductors, transformers, etc.) for applications requiring voltage isolation. In particular, the electronic device 100 utilizes space on both sides 111 and 112 of the substrate 110 to accommodate semiconductor dies and possibly other components without increasing the package dimensions. The further integration of the transformer windings W1 and W2 or other isolation components or features in certain implementations of the substrate 110 provides additional integration without increasing the size of the electronic device 100. The electronic device 100 provides a low-cost solution to enable high power and circuit density with optional integrated isolation.

The double-sided hybrid package configuration uses both sides 111 and 112 of the substrate 110 to facilitate these and other advantages. In the illustrated example, the semiconductor dies 121, 122, and 141-144 are electrically interconnected with circuitry of the device 100 by corresponding bond wires 126, and the semiconductor dies 123, 124, 131, and 132 are electrically interconnected by flip chip connections to conductive features of the respective first and second sides 111 and 112 of the substrate 110. In other implementations, any suitable electrical interconnections can be used for the semiconductor dies, including bond wires 126, flip chip connections, or combinations thereof on either or both sides 111, 112 of the substrate 110, including connections from a semiconductor die to one of the leads 109 or to other circuits or components of the electronic device 100.

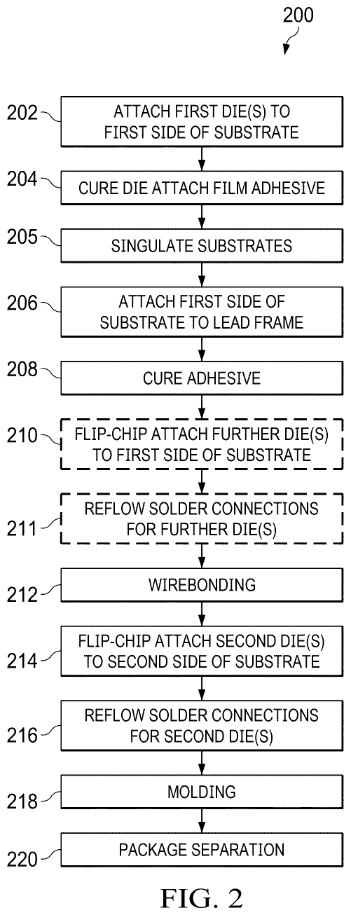

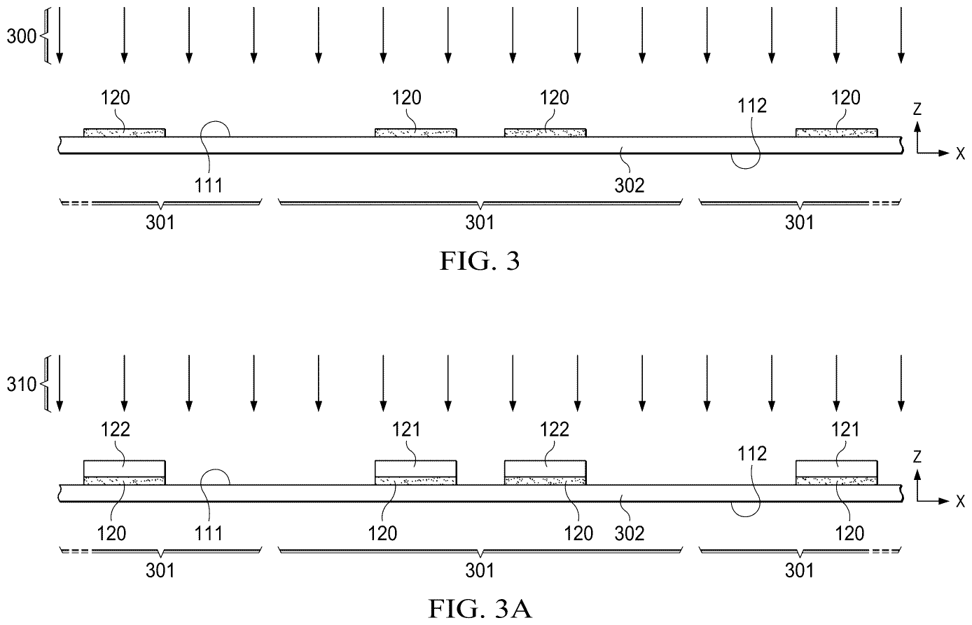

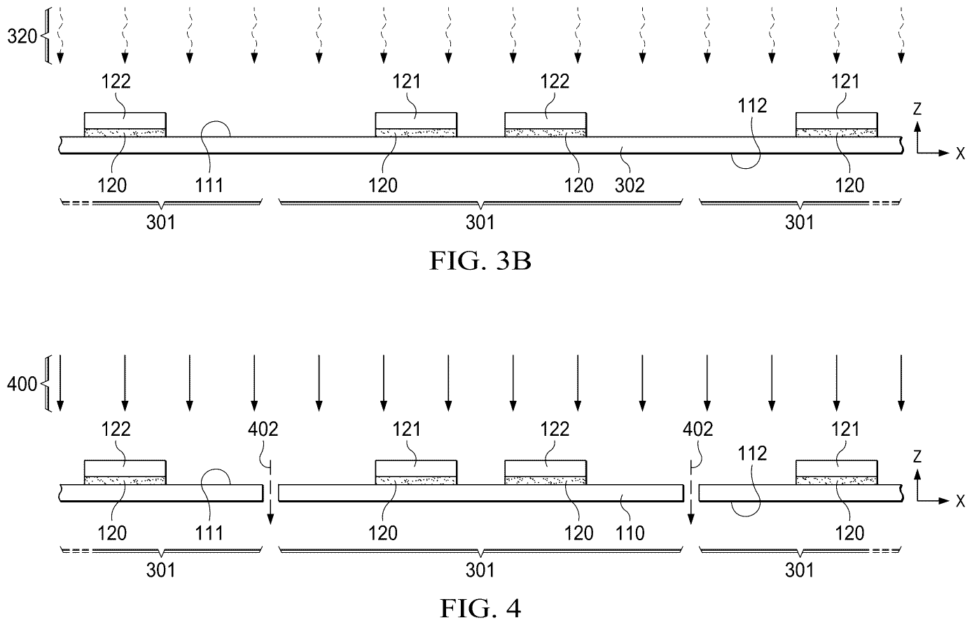

Referring also to FIGS. 2-11, FIG. 2 shows a method 200 of fabricating a semiconductor device, and FIGS. 3-11 show the semiconductor device 100 undergoing fabrication processing according to an implementation of the method 200.

The method 200 begins at 202 and 204 in FIG. 2 with an initial die attachment to attach one or more semiconductor dies to a side of a starting substrate panel array 302. In one example, the substrate panel array 302 includes rows and columns of unit areas 301, each corresponding to a prospective substrate 110 as described above, the substrate panel array 302 has a first side 111 and a second side 112 corresponding to the sides of the ultimately formed substrates 110. FIGS. 3-3B illustrate one example, in which the above described semiconductor dies 121-124 are attached to the first side 111 of the substrate 110.

In FIG. 3, an adhesive formation process 300 is performed that forms the adhesive (e.g., die attach film) 120 along select portions in each unit area 301 of a substrate array panel 302. Any suitable adhesive formation process 300 and die attach film or other adhesive 120 can be used. In one example the process 300 is a dispensing, silk screening, or printing process that forms the adhesive 120 on to the first side 111 of the substrate panel array 302, including four designated portions of the first side 111 corresponding to the desired locations of the semiconductor dies 121-124 as described above in connection with FIGS. 1-1B in each unit area 301.

A process 310 is performed in FIG. 3A that attaches the appropriate semiconductor dies (e.g., an instance of each of the semiconductor dies 121-124 in each unit area 301) to the previously formed adhesive 120 along the first side 111 of the substrate panel array 302, for example, using automated pick and place equipment (not shown). In the illustrated example, the die attach processing at 202 in FIG. 2 attaches semiconductor dies 121-124 in each unit area 301 on the first side 111 of the substrate panel array 302. In other implementations, any suitable number of one or more semiconductor dies can be attached to the first side 111 in each unit area 301.

The method 200 continues at 204 in FIG. 2 with optional die attach film curing. FIG. 3B shows one example, in which a thermal curing process 320 is performed that cures the adhesive 120 in one or more locations in each unit area 301 of the substrate panel array 302. In other examples, a different curing process can be used (e.g., ultraviolet or UV curing, etc.) based on the type of die attach film or adhesive 120 used in a given implementation.

The method 200 continues at 205 in FIG. 2 with substrate separation or singulation from the starting substrate panel array structure 302. FIG. 4 shows one example, in which a substrate singulation or separation process 400 is performed that separates the individual substrates 110 from the starting panel array structure along lines 402. In one example, the separation process 400 is a saw cutting process. In other implementations, different separation processes and tools can be used, such as laser cutting, chemical etching, etc. (not shown).

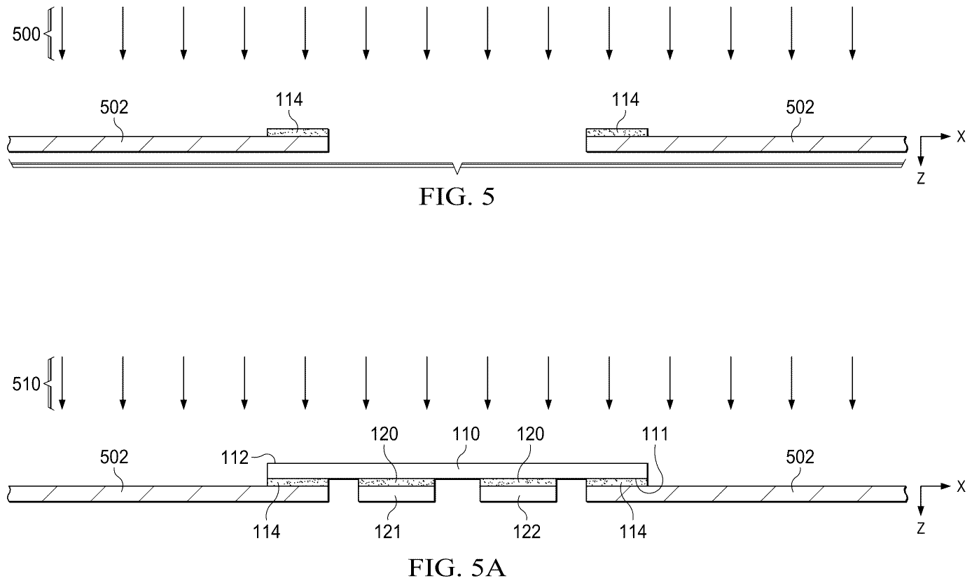

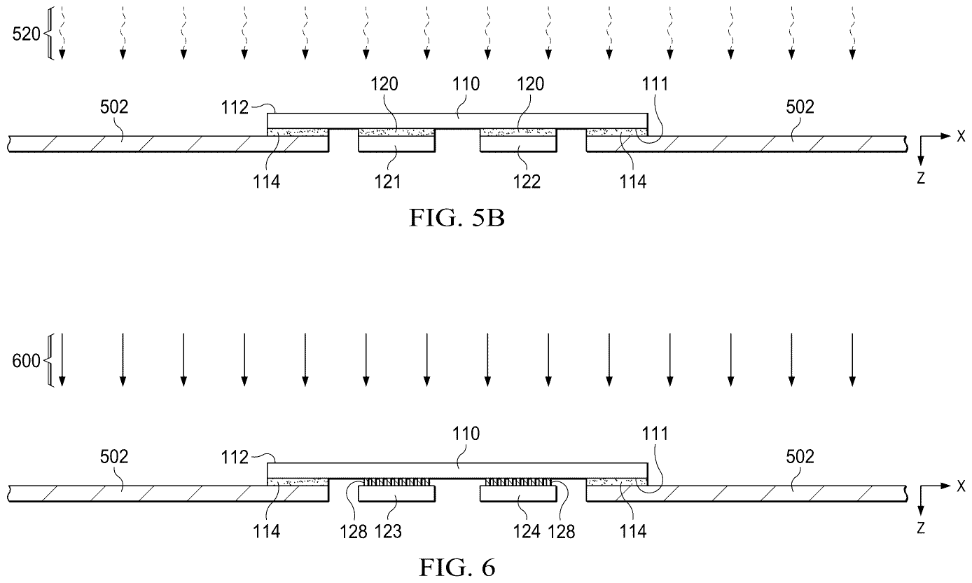

The method 200 continues at 206 and 208 in FIG. 2 with substrate attachment to a lead frame structure. In one example, a lead frame panel array structure is used having rows and columns of unit areas, each corresponding to a subsequently separated semiconductor device after packaging operations. FIGS. 5-10 show one example unit area of a starting lead frame 502 undergoing fabrication processing according to an implementation of the method 200 of FIG. 2.

In the illustrated example, the method 200 includes attaching at least a portion of the first side 111 of the substrate 110 to a portion of a top side of the lead frame 502 at 206 in FIG. 2, an example of which is illustrated in FIGS. 5 and 5A. In FIG. 5, an adhesive formation process 500 is performed (e.g., dispensing, silk screening, printing, etc.) that forms the adhesive 114 in select portions of the top side of the lead frame 502 (e.g., the corners of the die attach pad portions shown in the finished electronic device example 100 of FIG. 1A above). Any suitable adhesive 114 can be used.

A process 510 is performed in FIG. 5A that attaches the first side 111 of the previously processed and singulated substrate 110 to the previously formed adhesive 114 along the top side of the lead frame 502 in each unit area, for example, using automated pick and place equipment (not shown). The method 200 in one example continues at 208 in FIG. 2 with optional substrate attachment adhesive curing. FIG. 5B shows one example, in which a thermal curing process 520 is performed that cures the adhesive 114 in one or more locations in each unit area of the lead frame panel array 502. In other examples, a different curing process can be used (e.g., ultraviolet or UV curing, etc.) based on the type of substrate attach adhesive 114 used in a given implementation.

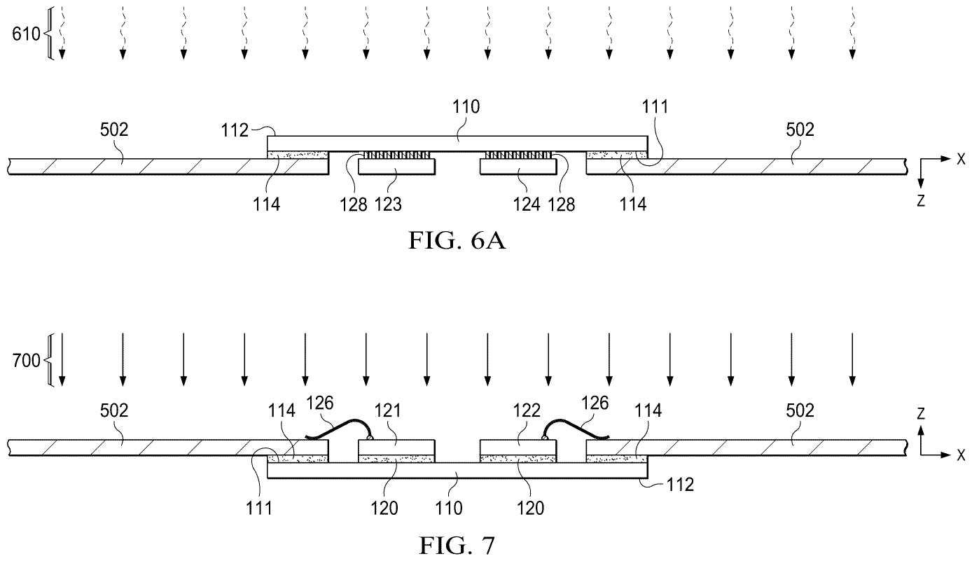

In the illustrated example, the method 200 continues at 210 and 211 in FIG. 2 with forming flip chip connections to attach the additional semiconductor dies 123 and 124 to conductive features of the first side 111 of the substrate 110. FIG. 6 shows one example, in which a flip chip die attach process 600 is performed that attaches the conductive terminals 128 of the semiconductor dies 123 and 124 to the corresponding portions of the first side 111 of the substrate 110. In one example, an optional solder reflow process can be performed at 211 in FIG. 2 to reflow the solder to create solder connections between the conductive terminals 128 of the semiconductor dies 123 and 124 and the corresponding conductive features along the first side 111 of the substrate 110. FIG. 6A shows one example, in which a thermal reflow process 610 is performed that reflows the solder of the flip chip connections of the die terminals 128 to the conductive features of the first side 111 of the substrate 110. In another implementation, where no flip chip die attachments or other surface mount components are to be attached to the first side 111 of the substrate 110, the processing at 210 and 211 in FIG. 2 can be omitted, or may be optionally performed earlier in the method 200, for example, prior to singulating the substrates at 205.

The method 200 in the illustrated example continues at 212 with wire bonding. FIG. 7 shows one example, in which a wire bonding process 700 is performed that forms the bond wires 126 between corresponding conductive terminals (e.g., bond pads) along the front sides of the attached semiconductor dies 121 and 122 and corresponding connection points (e.g., prospective leads of the lead frame 502). The wire bonding processing at 212 in FIG. 2 may also be used to form the other bond wire connections (e.g., FIG. 1A above) in each unit area of the lead frame panel array.

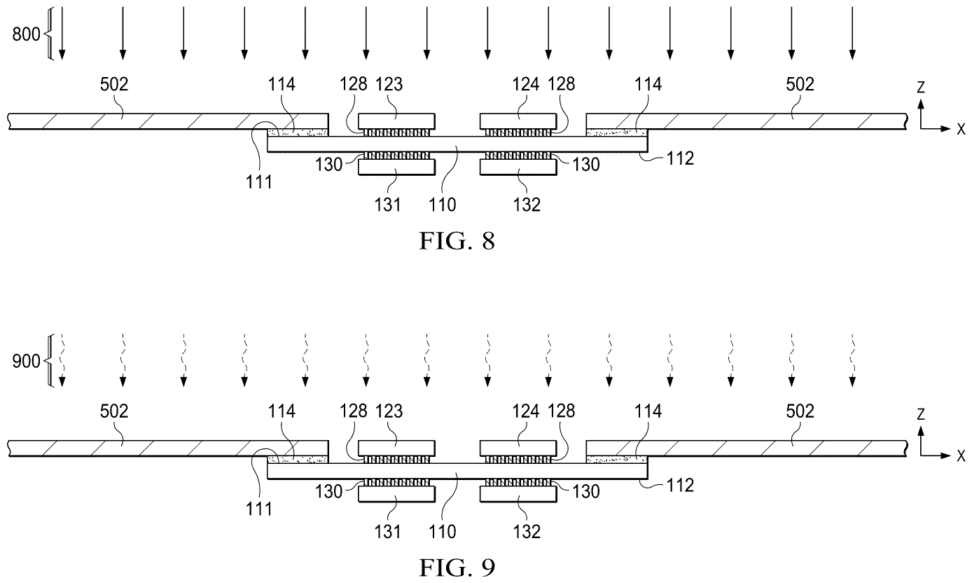

The method 200 continues at 214 in FIG. 2 with flip chip die attachment of the second die 131 and any further flip chip attached semiconductor dies (and/or any other surface mount components, not shown) to the second side 112 of the substrate 110. FIG. 8 shows one example, in which another flip chip die attach process 800 is performed that attaches the conductive terminals 130 of the semiconductor dies 131 and 132 to the corresponding portions of the second side 112 of the substrate 110. In one example, an optional solder reflow process can be performed at 216 in FIG. 2 to reflow the solder to create solder connections between the conductive terminals 130 of the semiconductor dies 131 and 132 and the corresponding conductive features along the second side 112 of the substrate 110. FIG. 9 shows one example, in which a thermal reflow process 900 is performed that reflows the solder of the flip chip connections of the die terminals 130 to the conductive features of the second side 112 of the substrate 110.

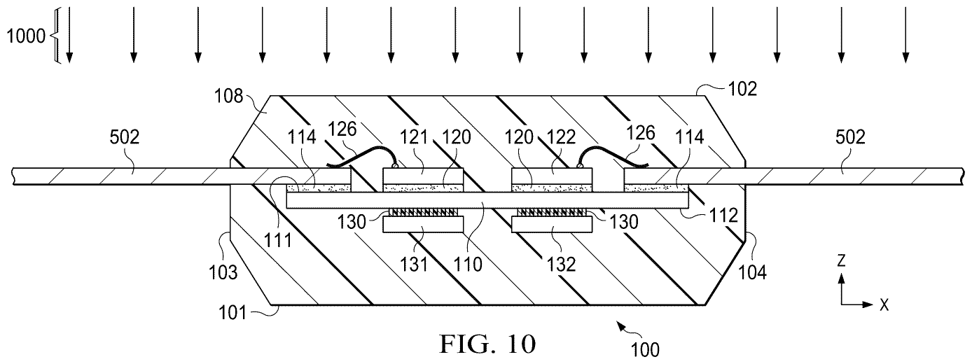

The method 200 continues at 218 in FIG. 2 with molding processing to form the package structure 108. FIG. 10 shows one example, in which a molding process 1000 is performed that forms the package structure 108 with the above-described sides 101-104. In one example, the lead frame panel array structure allows for concurrent molding of multiple unit areas, where the molding process 1000 in one example can form a single or shared molded package structure 108 along an entire column of unit areas, which are subsequently separated such as by saw cutting or other separation processing (not shown). In another example, the molding process 1000 uses a mold structure (not shown) having individual cavities for corresponding unit areas of the lead frame panel array configuration, and each of the individual cavities forms the corresponding ends or sides 105 and 106 of the individual molded package structures 108.

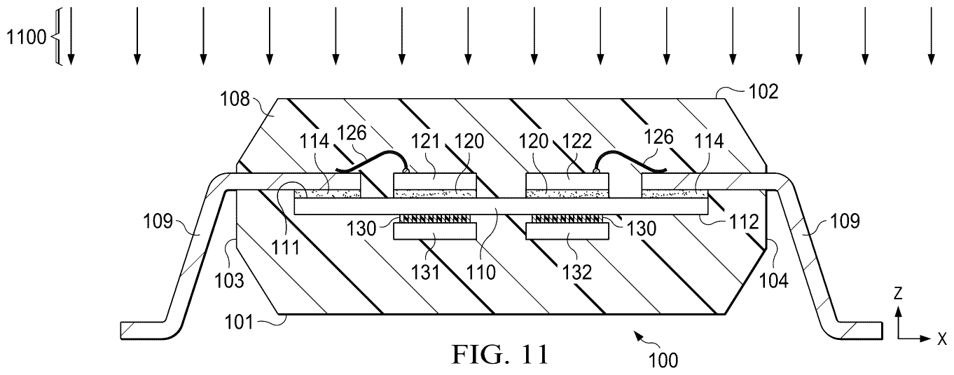

The method 200 in the illustrated example continues at 220 with package separation, which can include lead trimming and forming operations. FIG. 11 shows one example, in which a package separation process 1100 is performed that trims the prospective leads between adjacent unit areas of the lead frame panel array structure, followed by lead forming operations using suitable tooling (not shown) that forms the bends and creates the illustrated gullwing leads 109 of each separated semiconductor device 100, as further illustrated and described above in connection with FIGS. 1-1B.

Modifications are possible in the described embodiments, and other embodiments are possible, within the scope of the claims.

The following is claimed:

1. An electronic device, comprising:
a substrate having opposite first and second sides, the first side attached to a metal structure;
a first semiconductor die attached to the first side of the substrate;
a bond wire connected to the first semiconductor die; and
a second semiconductor die attached to the second side of the substrate.

2. The electronic device of claim 1, wherein the metal structure is a lead.

3. The electronic device of claim 1, wherein the substrate includes a winding.

4. The electronic device of claim 1, further comprising a package structure that encloses the first and second semiconductor dies and the bond wire.

5. The electronic device of claim 1, wherein the second semiconductor die includes flip chip connections to conductive features of the second side of the substrate.

6. The electronic device of claim 1, further comprising a third semiconductor die having flip chip connections to conductive features of the first side of the substrate.

7. The electronic device of claim 1, wherein the bond wire is connected between a conductive feature of the first semiconductor die and a conductive metal lead of the electronic device.

8. The electronic device of claim 1, wherein the bond wire is connected between a conductive feature of the first semiconductor die and a conductive feature of a further semiconductor die of the electronic device.

9. The electronic device of claim 1, wherein the bond wire is connected between a conductive feature of the first semiconductor die and a conductive feature of the first side of the substrate.

10. A system, comprising:
a circuit board having a conductive feature; and
an electronic device, including:
a conductive terminal that is soldered to the conductive feature of the circuit board;
a substrate having opposite first and second sides, the first side attached to a metal structure;
a first semiconductor die attached to the first side of the substrate;
a bond wire connected to the first semiconductor die; and
a second semiconductor die attached to the second side of the substrate.

11. The system of claim 10, wherein the metal structure is a lead.

12. The system of claim 10, wherein the substrate includes a winding.

13. The system of claim 10, wherein the second semiconductor die includes flip chip connections to conductive features of the second side of the substrate.

14. The system of claim 10, wherein the electronic device includes a third semiconductor die having flip chip connections to conductive features of the first side of the substrate.

15. A method of fabricating an electronic device, the method comprising:
attaching a first semiconductor die to first side of a substrate;
attaching the first side of the substrate to a lead frame;
connecting a bond wire to a conductive feature of the first semiconductor die; and
forming flip chip connections to attach a second semiconductor die to conductive features of an opposite second side of the substrate.

16. The method of claim 15, further comprising forming a package structure that encloses the first and second semiconductor dies and the bond wire.

17. The method of claim 15, wherein the bond wire is connected to the conductive feature of the first semiconductor die before the flip chip connections are formed to attach the second semiconductor die to the conductive features of the second side of the substrate.

18. The method of claim 15, further comprising forming flip chip connections to attach a third semiconductor die to conductive features of the first side of the substrate.

19. The method of claim 18, wherein the bond wire is connected to the conductive feature of the first semiconductor die after the flip chip connections are formed to attach the third semiconductor die to the conductive features of the first side of the substrate.

20. The method of claim 19, further comprising, after forming the flip chip connections to attach the second semiconductor die to the conductive features of the second side of the substrate, forming a package structure that encloses the first and second semiconductor dies and the bond wire.
